(19) United States
(12) Patent Application Publication
(10) Pub. No.: US 2018/0366077 A1
(43) Pub. Date: Dec. 20, 2018

(54) PIXEL DRIVE VOLTAGE OUTPUT CIRCUIT AND DISPLAY DRIVER

(71) Applicant: LAPIS Semiconductor Co., Ltd., Yokohama (JP)

(72) Inventor: Koji HIGUCHI, Yokohama (JP)

(73) Assignee: LAPIS Semiconductor Co., Ltd., Yokohama (JP)

(21) Appl. No.: 16/009,400

(22) Filed: Jun. 15, 2018

(30) Foreign Application Priority Data
Jun. 16, 2017 (JP) 2017-118378

(51) Int. Cl. G09G 3/36; H03F 3/45; H03F 1/02

(52) U.S. Cl. CPC G09G 3/3614; H03F 3/45269; H03F 1/0211; G09G 3/3688; G09G 2330/02; G09G 2310/0291; G09G 3/3677; G09G 3/3696

(57) ABSTRACT

Provided is a pixel drive voltage output circuit which includes: an operational amplifier ; a switching unit configured to connect a first power source line with a high-level power source terminal or a middle-level power source terminal and to connect a second power source line with the middle-level power source terminal or a low-level power source terminal; a first transistor having a first conductivity type with a first terminal connected to the first power source line, a second terminal connected to a signal output terminal, and a control terminal connected to a first output terminal of the operational amplifier; and a second transistor having a second conductivity type with a first terminal connected to the second power source line, a second terminal connected to the signal output terminal, and a control terminal connected to a second output terminal of the operational amplifier.

### BACKGROUND OF THE INVENTION

### 1. Field of the Invention

The present invention relates to a pixel drive voltage output circuit in a display driver for driving a display.

### 2. Description of the Related Art

The display device is provided with a display driver for driving a display such as a liquid crystal display. Employed as such a display driver is a display driver of an inversion drive scheme by which a polarity of gradation voltages are inverted for each frame period of a video signal or for each field display period to drive data lines (for example, Japanese Patent No. 5777300).

For example, the display driver of the inversion drive scheme has a positive-side output circuit between a high-level power source voltage VDDH and a middle-level power source voltage VDM, and a negative-side output circuit between the middle-level power source voltage VDM and a low-level power source voltage VSSH. While switching the output circuits depending on the polarity, the display driver of the inversion drive scheme outputs a positive gradation voltage (hereafter, a positive voltage) and a negative gradation voltage (hereafter, a negative voltage) via the same output terminal.

For example, the positive-side output circuit has a P-channel type MOS transistor (positive-side PMOS transistor) and an N-channel type MOS transistor (positive-side NMOS transistor) with the drains connected together. Likewise, the negative-side output circuit has, for example, a P-channel type MOS transistor (negative-side PMOS transistor) and an N-channel type MOS transistor (negative-side NMOS transistor) with the drains connected together.

The positive-side PMOS transistor has the source to which the high-level power source voltage VDDH is applied. The positive-side NMOS transistor has the source to which the middle-level power source voltage VDM is applied. The negative-side PMOS transistor has the source to which the middle-level power source voltage VDM is applied. The negative-side NMOS transistor has the source to which the low-level power source voltage VSSH is applied.

The connection node of the drains of the positive-side PMOS transistor and NMOS transistor, which are the output terminals of the positive-side output circuit, and the connection node of the drains of the negative-side PMOS transistor and NMOS transistor, which are the output terminals of the negative-side output circuit, are connected to a common output line.

When the positive voltage is outputted, the output pair of an operational amplifier is connected to the respective gates of the positive-side PMOS transistor and the positive-side NMOS transistor, whereas the connections between the output pair of the operational amplifier and the gates of the negative-side PMOS transistor and the negative-side NMOS transistor are interrupted. On the other hand, when the negative voltage is outputted, the output pair of the operational amplifier is connected to the respective gates of the negative-side PMOS transistor and the negative-side NMOS transistor, whereas the connections between the output pair of the operational amplifier and the gates of the positive-side PMOS transistor and the positive-side NMOS transistor are interrupted.

However, when the positive voltage is outputted, there is a possibility that a current flows in the forward direction of a parasitic diode from the drain of the negative-side PMOS transistor connected via the output line to the bulk (the back gate). It is thus necessary to change the potential of the bulk of the negative-side PMOS transistor to the high-level power source voltage VDDH. Likewise, when the negative voltage is outputted, since there is a possibility that a current flows in the forward direction of a parasitic diode from the drain of the positive-side NMOS transistor to the bulk, it is thus necessary to change the potential of the bulk of the positive-side NMOS transistor to the low-level power source voltage VSSH.

This causes a back bias of ½ VDDH to VDDH to be applied to the negative-side PMOS transistor and the positive-side NMOS transistor. Due to the effects of the back bias, the threshold voltage Vth of the negative-side PMOS transistor and the positive-side NMOS transistor is significantly shifted in property as compared with the threshold value Vth of the negative-side NMOS transistor and the positive-side PMOS transistor to which no back bias is applied. Therefore, there is a difference in output property between the positive-side output circuit and the negative-side output circuit.

The present invention has been developed in view of the aforementioned problem, and an object of the present invention is to provide a display driver of an inversion drive scheme that has output circuits of a uniform output property in a positive output and a negative output.

### SUMMARY OF THE INVENTION

A pixel drive voltage output circuit according to the present invention is configured to output, to a display, a pixel drive voltage signal depending on a video signal. The output circuit includes: a high-level power source terminal configured to be supplied with a high-level power source voltage; a low-level power source terminal configured to be supplied with a low-level power source voltage lower than the high-level power source voltage; a middle-level power source terminal configured to be supplied with a middle-level power source voltage that is a voltage between the high-level power source voltage and the low-level power source voltage; a signal output terminal configured to output the pixel drive voltage signal; an operational amplifier having a first output terminal and a second output terminal, the operational amplifier being configured to receive a gradation voltage signal representative of the video signal and to amplify said gradation voltage signal thereby to output the amplified signal via the first output terminal and the second output terminal; a first power source line configured to supply a first power source voltage to the operational amplifier; a second power source line configured to supply a second power source voltage to the operational amplifier; a switching unit configured to switch between a connection of the first power source line with the high-level power source terminal and with the middle-level power source terminal and to switch between a connection of the second power source line with the middle-level power source terminal and with the low-level power source terminal; a first transistor having a first conductivity type, with a first terminal connected to the first power source line, a second terminal connected to the signal output terminal via an output node, and a control terminal connected to the first output terminal of the operational amplifier; and a second transistor having a second conductivity type which is opposite to said first conductivity type, with a first terminal connected to the second power source line, a second terminal connected to the signal output terminal via the output node, and a control terminal connected to the second output terminal of the operational amplifier. A display driver according to the present invention is configured to supply first to n-th pixel drive voltage signals to a display on the basis of a video signal that includes a train of n pieces of pixel data (n is an integer equal to two or greater). The display driver includes: a gradation voltage conversion unit configured to convert the n pieces of pixel data into first to n-th gradation voltage signals; and an output unit configured to output the first to n-th pixel drive voltage signals depending on the first to n-th gradation voltage signals. The output unit includes: a high-level power source supply line configured to be supplied with a high-level power source voltage; a low-level power source supply line configured to be supplied with a low-level power source voltage lower than the high-level power source voltage; a middle-level power source supply line configured to be supplied with a middle-level power source voltage that is a voltage between the high-level power source voltage and the low-level power source voltage; first to n-th signal output terminals configured to output the first to n-th pixel drive voltage signals; and first to n-th output circuits connected to the first to n-th signal output terminals. Each of the first to n-th output circuits includes: an operational amplifier having a first output terminal and a second output terminal, the operational amplifier being configured to output, via the first output terminal and the second output terminal, a corresponding gradation voltage signal of the first to n-th gradation voltage signals; a first power source line configured to supply a first power source voltage to the operational amplifier; a second power source line configured to supply a second power source voltage to the operational amplifier; a switching unit configured to switch between a connection of the first power source line with the high-level power source supply line and with the middle-level power source supply line and to switch between a connection of the second power source line with the middle-level power source supply line and with the low-level power source supply line; a first transistor having a first conductivity type, with a first terminal connected to the first power source line, a second terminal connected to a corresponding signal output terminal of the first to n-th signal output terminals via an output node, and a control terminal connected to the first output terminal of the operational amplifier; and a second transistor having a second conductivity type which is opposite to said first conductivity type, with a first terminal connected to the second power source line, a second terminal connected to a corresponding signal output terminal of the first to n-th signal output terminals via the output node, and a control terminal connected to the second output terminal of the operational amplifier.

According to the output circuit of the present invention, in the display driver of the inversion drive scheme, it is possible to provide uniform output properties in positive output and negative output.

### BRIEF DESCRIPTION OF THE DRAWINGS

The features of the present invention will be described in the following descriptions with reference to the accompanying drawings, in which:

FIG. 1 is a block diagram illustrating a configuration of a display device that includes output circuits according to the present invention;

FIG. 2 is a block diagram illustrating an embodiment of a configuration of a source driver that includes output circuits according to the present invention;

FIG. 3 is a circuit diagram illustrating a configuration of an output circuit according to the present invention;

FIG. 4 is a time chart indicative of the operation of switch control in an output circuit;

FIG. 5 is a circuit diagram illustrating a configuration of an output circuit according to a comparative example;

FIG. 6 is a circuit diagram illustrating the configuration of output circuits for a plurality of channels and changes in the configuration due to a polarity inversion; and

FIG. 7 is a circuit diagram illustrating a modified example of a configuration of output circuits for a plurality of channels.

### DETAILED DESCRIPTION OF THE INVENTION

Now, with reference to the drawings, a description will be given of embodiments of the present invention. Note that throughout the descriptions and the attached drawings in the embodiments below, substantially the same or equivalent components are denoted by the same reference symbols.

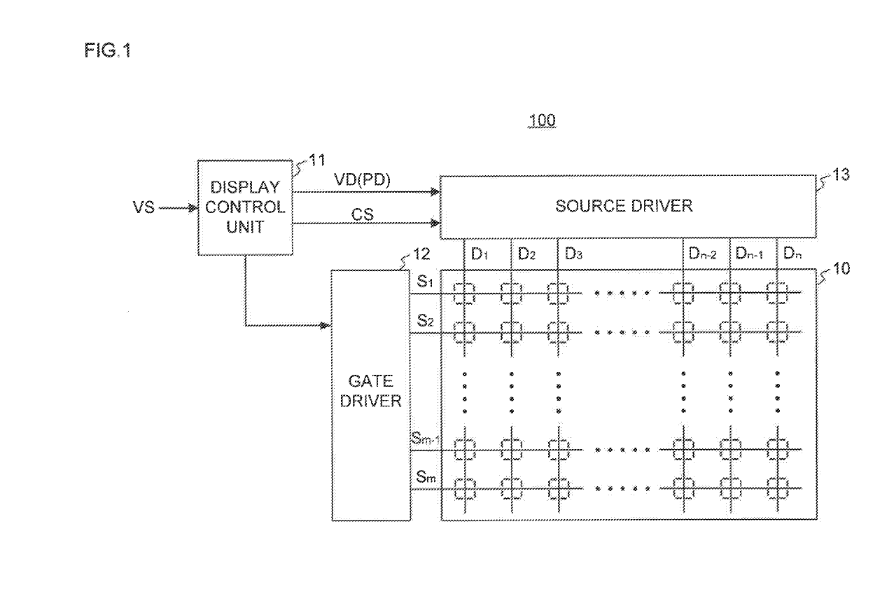

FIG. 1 is a block diagram illustrating the configuration of a display device 100 that includes output circuits according to an embodiment. For example, the display device 100 is a liquid crystal display device configured to drive a display 10 such as a liquid crystal display by the inversion drive scheme. The display device 100 includes the display 10, a display control unit 11, a gate driver 12, and a source driver 13.

The display 10 is provided with m horizontal scanning lines S₁ to Sₘ that extend in the horizontal direction of a two-dimensional screen (m is an integer equal to two or greater) and n data lines D₁ to Dₙ that extend in the vertical direction of the two-dimensional screen (n is an integer equal to two or greater). At respective areas of intersections of the horizontal scanning lines and the data lines, display cells serving as pixels (denoted by broken lines in FIG. 1) are disposed in the shape of a matrix.

The display control unit 11 supplies, to the source driver 13 on the basis of an input video signal VS, an image data signal VD that includes a train of pieces of pixel data PD indicative of the brightness level of each pixel. Furthermore, the display control unit 11 detects a horizontal sync signal from the input video signal VS and then supplies the resulting signal to the gate driver 12. Furthermore, the display control unit 11 supplies, to the source driver 13, a switching control signal CS for use in controlling the polarity inversion in the inversion drive.

The gate driver 12 produces a scanning signal in synchronism with the horizontal sync signal supplied from the display control unit 11 and then sequentially supplies the resulting signal to each of the horizontal scanning lines S₁ to Sₘ of the display 10.

The source driver 13 produces n pixel drive voltages G₁ to Gₙ for each one horizontal scanning line on the basis of the image data signal VD and then applies the resulting voltages to the data lines D₁ to Dₙ of the display 10. At this time, the source driver 13 applies the voltages to the data lines D₁ to Dₙ while inverting the polarity of the pixel drive voltages G₁ to Gₙ in response to the switching control signal CS supplied from the display control unit 11.

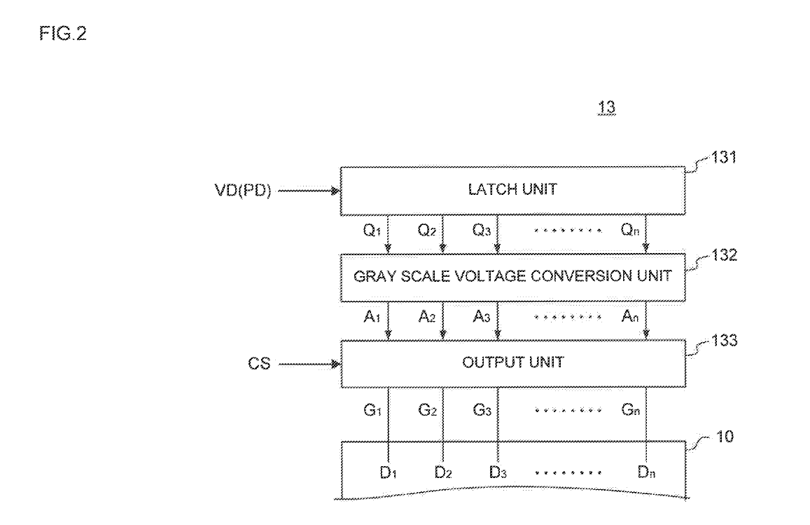

FIG. 2 is a block diagram illustrating the internal configuration of the source driver 13 as a display driver. The source driver 13 includes a latch unit 131, a gradation voltage conversion unit 132, and an output unit 133.

The latch unit 131 sequentially captures a train of pieces of pixel data PD included in the image data signal VD supplied from the display control unit 11. Each time n pieces of pixel data PD for one horizontal scanning line are captured, the latch unit 131 outputs the n pieces of pixel data PD as pixel data Q₁ to Qₙ to the gradation voltage conversion unit 132.

The gradation voltage conversion unit 132 converts each of the pixel data Q₁ to Qₙ supplied from the latch unit 131 into positive or negative gradation voltages A₁ to Aₙ having a voltage value corresponding to a luminance gradation expressed by the pixel data and then supplies the resulting voltages to the output unit 133.

The output unit 133 produces voltages, to which the gradation voltages A₁ to Aₙ were amplified, as pixel drive voltages G₁ to G. The output unit 133 supplies the pixel drive voltages G₁ to Gₙ to each of the data lines D₁ to Dₙ of the display 10 while inverting the polarity of the pixel drive voltages G₁ to Gₙ in response to the switching control signal CS. The output unit 133 has output circuits for the n channels corresponding to the number of the data lines D₁ to Dₙ.

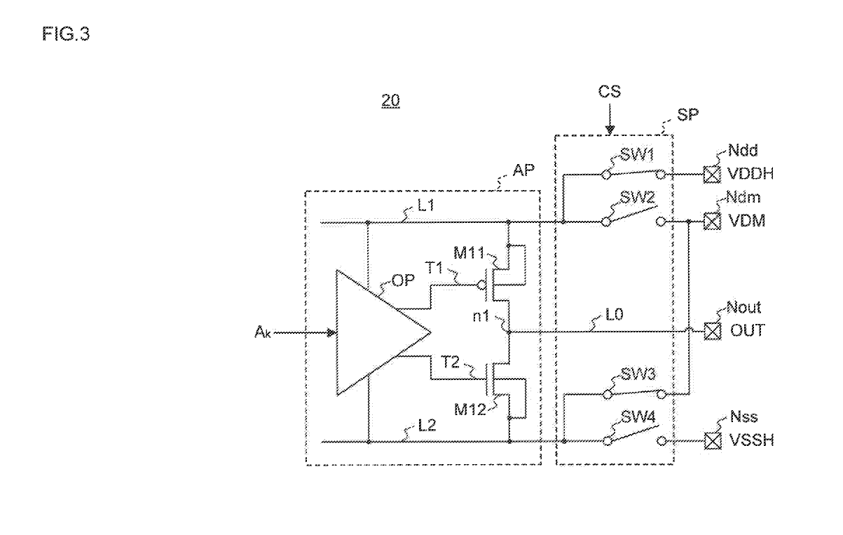

FIG. 3 is a circuit diagram illustrating a configuration of an output circuit 20, namely a pixel drive voltage output circuit, which is one of the output circuits for the n channels. The output circuit 20 has an output amplifier AP, switches SW1, SW2, SW3, and SW4, a high-level power source terminal Ndd configured to receive a high-level power source voltage VDDH, a low-level power source terminal Nss configured to receive a low-level power source voltage VSSH, a middle-level power source terminal Ndm configured to receive a middle-level power source voltage VDM that is a voltage (for example, an intermediate voltage) between the high-level power source voltage VDDH and the low-level power source voltage VSSH, and an output terminal Nout that is the output terminal of the pixel drive voltage Gₖ (k=1, 2, . . . , n).

The output amplifier AP includes an operational amplifier OP, and transistors M11 and M12. The transistor M11 is a P-channel type MOS transistor of a first channel type. The transistor M12 is an N-channel type MOS transistor of a channel type opposite to the first channel type.

The operational amplifier OP is connected to a first power source line L1 and a second power source line L2. The operational amplifier OP performs amplification on the basis of a power source voltage (a first power source voltage or a second power source voltage) supplied from each of the power source lines. The operational amplifier OP has a first output terminal T1 connected to the gate (control terminal) of the transistor M11. The operational amplifier OP has a second output terminal T2 connected to the gate (control terminal) of the transistor M12. The operational amplifier OP supplies a voltage, to which a gradation voltage Ak was amplified, to the gate of each of the transistors M11 and M12.

The transistor M11 has the source (first terminal) connected to the first power source line L1. The transistor M11 has the drain (second terminal) connected to the drain of the transistor M12 and an output line L0 via a node n1. Furthermore, the source and the bulk (back gate) of the transistor M11 are connected together.

The transistor M12 has the source (first terminal) connected to the second power source line L2. The transistor M12 has the drain (second terminal) connected to the drain of the transistor M11 and the output line L0 via the node n1. Furthermore, the source and the bulk (back gate) of the transistor M12 are connected together.

The power source line L1 is connected to the high-level power source terminal Ndd via the switch SW1 and connected to the middle-level power source terminal Ndm via the switch SW2. The power source line L2 is connected to the middle-level power source terminal Ndm via the switch SW3 and connected to the low-level power source terminal Nss via the switch SW4.

The switches SW1 and SW2 are controlled so as to be complementarily turned ON (into a connected state) or OFF (into a disconnected state). Likewise, the switches SW3 and SW4 are controlled so as to be complementarily turned ON or OFF. The switches SW1 to SW4 (which are collectively illustrated as a switch unit SP in FIG. 3) are supplied with the switching control signal CS. Each of the switches SW1 to SW4 is controlled so as to be switched between ON and OFF in response to the switching control signal CS.

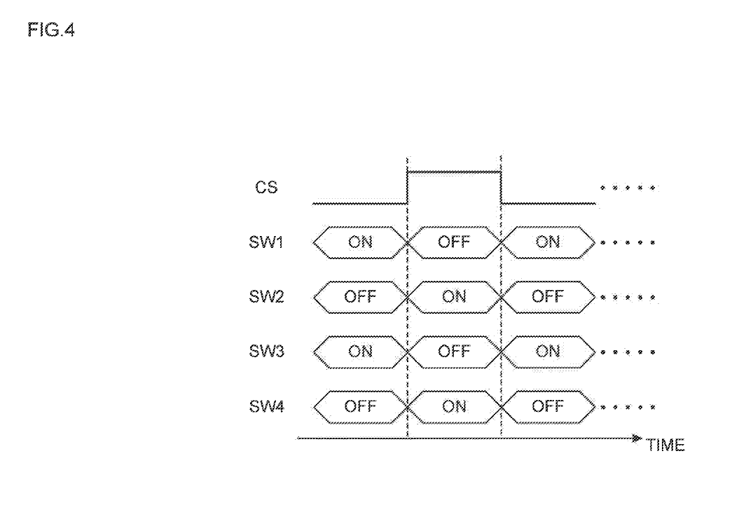

FIG. 4 is a time chart indicative of an embodiment of the timing of switching control of the switch SW1 to SW4. The switching control signal CS has a signal level that is varied between logic level 1 (H level) and logic level 0 (L level), for example, depending on the polarity of the gradation voltages A₁ to Aₙ.

While the switching control signal CS is at the L level, the switch SW1 is ON, the switch SW2 is OFF, the switch SW3 is ON, and the switch S4 is OFF. This causes the first power source line L1 to be connected to the high-level power source terminal Ndd. The second power source line L2 is connected to the middle-level power source terminal Ndm. The operational amplifier OP is supplied as an operation power source with the high-level power source voltage VDDH and the middle-level power source voltage VDM. The source of the transistor M11 is supplied with the high-level power source voltage VDDH. The source of the transistor M12 is supplied with the middle-level power source voltage VDM. Thus, the output amplifier AP operates on the basis of the high-level power source voltage VDDH and the middle-level power source voltage VDM and outputs a positive pixel drive voltage Gₖ (hereafter a positive voltage) via the output terminal Nout.

While the switching control signal CS is at the H level, the switch SW1 is OFF, the switch SW2 is ON, the switch SW3 is OFF, and the switch SW4 is ON. This causes the first power source line L1 to be connected to the middle-level power source terminal Ndm. The second power source line L2 is connected to the low-level power source terminal Nss. The operational amplifier OP is supplied as an operation power source with the middle-level power source voltage VDM and the low-level power source voltage VSSH. The source of the transistor M11 is supplied with the middle-level power source voltage VDM. The source of the transistor M12 is supplied with the low-level power source voltage VSSH. Thus, the output amplifier AP operates on the basis of the middle-level power source voltage VDM and the low-level power source voltage VSSH and outputs a negative pixel drive voltage Gₖ (hereafter a negative voltage) via the output terminal Nout.

In comparison with an output circuit of a comparative example, a description will now be given of the effects that are acquired by the output circuit 20 of this embodiment.

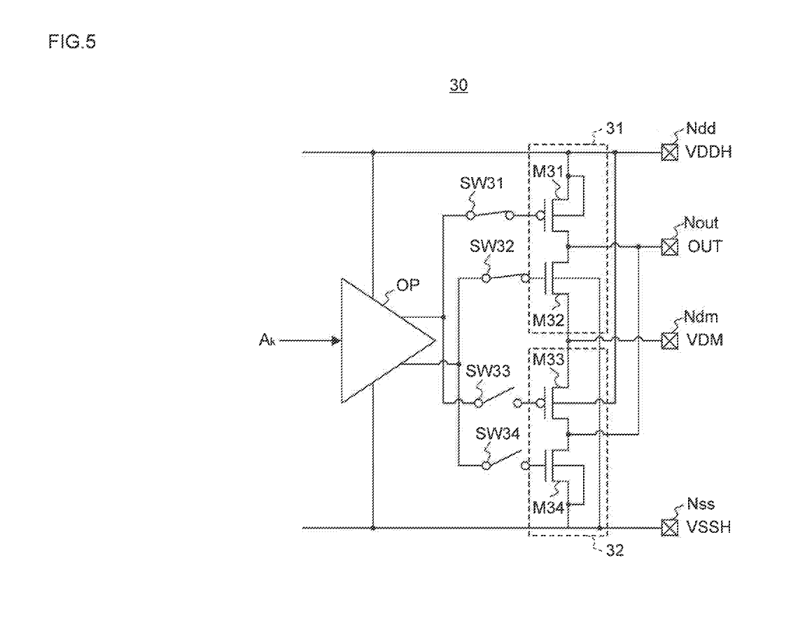

FIG. 5 is a circuit diagram illustrating an output circuit 30 of a comparative example. The output circuit 30 includes an operational amplifier OP, a positive-side output circuit 31, and a negative-side output circuit 32.

The positive-side output circuit 31 is configured from a transistor M31 that is a P-channel type MOS transistor and a transistor M32 that is an N-channel type MOS transistor. The transistor M31 has the source connected to the high-level power source terminal Ndd. The transistor M32 has the source connected to the middle-level power source terminal Ndm. The drains of the transistor M31 and the transistor M32 are connected together. The connection between the drains is connected to the output terminal Nout.

The negative-side output circuit 32 is configured from a transistor M33 that is a P-channel type MOS transistor and a transistor M34 that is an N-channel type MOS transistor. The transistor M33 has the source connected to the middle-level power source terminal Ndm. The transistor M34 has the source connected to the low-level power source terminal Nss. The drains of the transistor M33 and the transistor M34 are connected together. The connection between the drains is connected to the output terminal Nout.

The operational amplifier OP has a first output terminal connected to the gate of the transistor M31 via the switch SW31 or connected to the gate of the transistor M33 via the switch SW33. The switches SW31 and SW33 are complementarily turned ON or OFF. The operational amplifier OP has a second output terminal connected to the gate of the transistor M32 via the switch SW32 or connected to the gate of the transistor M34 via the switch SW34.

When the positive voltage is outputted, the switches SW31 and SW32 are turned ON, so that the positive-side output circuit 31 performs an output operation. When the negative voltage is outputted, the switches SW33 and SW34 are turned ON, so that the negative-side output circuit 32 performs an output operation.

In the output circuit 30 of the comparative example with the aforementioned configuration, the bulk of the transistor M33 is connected to the high-level power source terminal Ndd in order to prevent a current flowing to the bulk in the forward direction of a parasitic diode from the drain of the transistor M33 (a negative-side PMOS transistor) when the positive voltage is outputted. On the other hand, the bulk of the transistor M32 is connected to the low-level power source terminal Nss in order to prevent a current flowing to the bulk in the forward direction of a parasitic diode from the drain of the transistor M32 (a positive-side NMOS transistor) when the negative voltage is outputted.

This causes a back bias equivalent to ½ VDDH to VDDH to be applied to the transistors M32 and M33, of which threshold voltage properties are significantly shifted as compared with the negative-side NMOS transistor and the positive-side PMOS transistor to which no back bias is applied.

In contrast to this, as shown in FIG. 3, in the output circuit 20 of this embodiment, the source and the bulk of the transistor M11 are connected together and connected to the first power source line L1. On the other hand, the source and the bulk of the transistor M12 are connected together and connected to the second power source line L2.

Since this allows the source and the bulk of the transistor M11 to be connected to the same power source (the high-level power source voltage VDDH or the middle-level power source voltage VDM), no back bias will occur. Likewise, since the source and the bulk of the transistor M12 are connected to the same power source (the middle-level power source voltage VDM or the low-level power source voltage VSSH), no back bias will occur. Thus, the output circuit 20 of this embodiment has the same properties at the positive and negative sides.

Furthermore, in the output circuit 20 of this embodiment, unlike the output circuit of the comparative example, it is not necessary to switch between the transistor pairs that operate with the positive-side output circuit and the negative-side output circuit separately provided. It is thus possible to constitute an output circuit which is simplified and reduced in footprint.

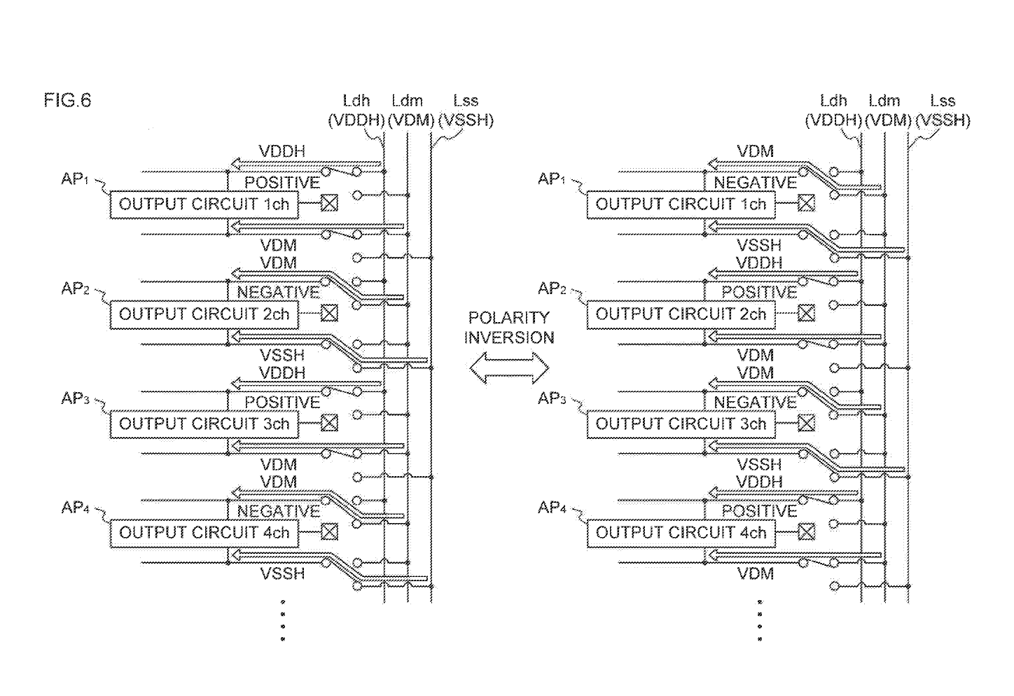

FIG. 6 is a circuit diagram illustrating a configuration of output circuits for a plurality of channels (ch) and changes in the configuration due to a polarity inversion. The output circuits of adjacent channels output pixel drive voltages of different polarities.

For example, when the output circuits of the odd channels (1ch, 3ch, . . . ) (a first output circuit group) output a positive voltage, the output circuits of the even channels (2ch, 4ch, . . . ) (a second output circuit group) output a negative voltage. At this time, as illustrated on the left in FIG. 6, in the output circuits of the odd channels (the output amplifiers AP_{'}, AP₃, . . . ), the first power source line is connected to a high-level power source supply line Ldh which is supplied with the high-level power source voltage VDDH, and a second power source line is connected to a middle-level power source supply line Ldm which is supplied with the middle-level power source voltage VDM. In the output circuits of the even channels (the output amplifier AP₂, AP₄, . . . ), the first power source line is connected to the middle-level power source supply line Ldm, and the second power source line is connected to a low-level power source supply line Lss which is supplied with the low-level power source voltage VSSH.

A polarity inversion causes the output circuits of the odd channels to output a negative voltage, whereas causing the output circuits of the even channels to output a positive voltage. At this time, as illustrated on the right in FIG. 6, in the output circuits of the odd channels (the output amplifiers AP1, AP3, . . . ), the first power source line is connected to the middle-level power source supply line Ldm, whereas the second power source line is connected to the low-level power source supply line Lss. In the output circuits of the even channels (the output amplifiers AP2, AP4, . . . ), the first power source line is connected to the high-level power source supply line Ldh, whereas the second power source line is connected to the middle-level power source supply line Ldm.

As described above, according to the output circuit of this embodiment, the connection between an output circuit and a power source is switched for the output circuits that output pixel drive voltages of the same polarity, thereby enabling output of a positive voltage and a negative voltage. It is thus possible to output the positive voltage and the negative voltage by the circuits of the same properties.

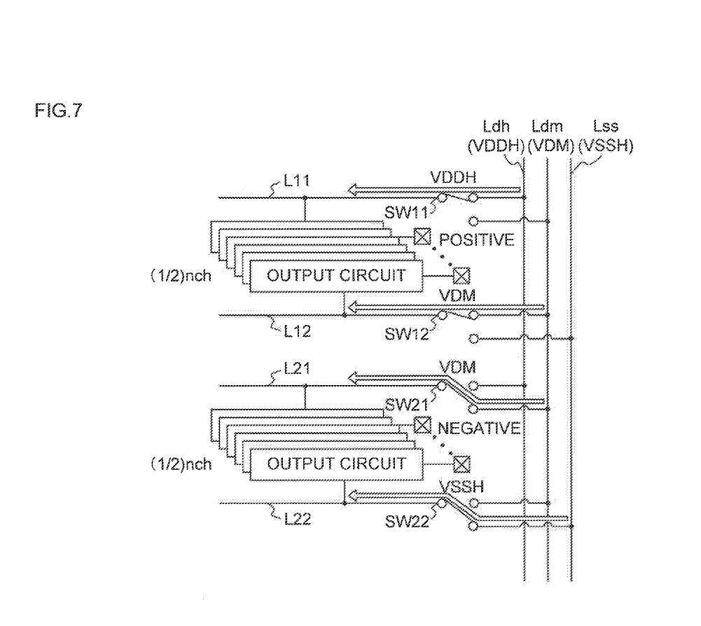

FIG. 7 is a circuit diagram illustrating a modified example of the configuration of output circuits for a plurality of channels. Here, output circuits for ½n ch (n is an even number) of the same operation are collectively connected to a power source via a common power source line and a switch. For example, in each of the output circuits for for ½n ch that are configured from the output circuits of the odd channels (the upper stage of FIG. 7), the first power source line is connected to the high-level power source supply line Ldh via a common line L11 and a switch SW11, whereas the second power source line is connected to the middle-level power source supply line Ldm via a common line L12 and a switch SW12. In each of the output circuits for ½n that are configured from the output circuits of the even channels (the lower stage of FIG. 7), the first power source line is connected to the middle-level power source supply line Ldm via a common line L21 and a switch SW21, whereas the second power source line is connected to the low-level power source supply line Lss via a common line L22 and a switch SW22.

According to such a configuration, it is possible to reduce the number of switches and the circuit area.

Note that the present invention is not limited to the aforementioned embodiments. For example, the configuration of each switch is not limited to those illustrated in the aforementioned embodiments. The switch unit SP (switching unit) only has to be configured so as to be capable of switching the connection destination of the power source line L1 between the high-level power source terminal Ndd and the middle-level power source terminal Ndm, while switching the connection destination of the power source line L2 between the middle-level power source terminal Ndm and the low-level power source terminal Nss.

Furthermore, the switching control of each switch according to the aforementioned embodiments was illustrated as an embodiment. The switching control only has to alternately switch between a first state and a second state. In the first state, the source of the transistor M11 and the first power source supply terminal of the operational amplifier OP are connected to the high-level power source terminal Ndd via the power source line L1, and the source of the transistor M12 and the second power source supply terminal of the operational amplifier OP are connected to the middle-level power source terminal Ndm via the power source line L2. In the second state, the source of the transistor M11 and the first power source supply terminal of the operational amplifier OP are connected to the middle-level power source terminal Ndm via the power source line L1, while the source of the transistor M12 and the second power source supply terminal of the operational amplifier OP are connected to the low-level power source terminal Nss via the power source line L2.

Furthermore, in the aforementioned embodiments, descriptions were given of such an embodiment in which the output circuits of the odd channels and the output circuits of the even channels that are alternately disposed output pixel drive voltages that have polarities different from each other. However, the mode of the disposition and connection of each output circuit is not limited to those mentioned above. The plurality of output circuits only have to be complementarily switched and connected to a power source terminal (power source supply line) so that the output circuits classified into the first output circuit group and the output circuits classified into the second output circuit group output pixel drive voltages of different polarities.

It is understood that the foregoing description and accompanying drawings set forth the preferred embodiments of the present invention at the present time. Various modifications, additions and alternative designs will, of course, become apparent to those skilled in the art in light of the foregoing teachings without departing from the spirit and scope of the disclosed invention. Thus, it should be appreciated that the present invention is not limited to the disclosed Examples but may be practiced within the full scope of the appended claims.

This application is based upon and claims the benefit of priority from the prior Japanese Patent Application No. 2017-118378 filed on Jun. 16, 2017, the entire contents of which are incorporated herein by reference.

What is claimed is:

1. A pixel drive voltage output circuit configured to output, to a display, a pixel drive voltage signal depending on a video signal, the output circuit comprising:
a high-level power source terminal configured to be supplied with a high-level power source voltage;
a low-level power source terminal configured to be supplied with a low-level power source voltage lower than said high-level power source voltage;
a middle-level power source terminal configured to be supplied with a middle-level power source voltage that is a voltage between said high-level power source voltage and said low-level power source voltage;
a signal output terminal configured to output said pixel drive voltage signal;
an operational amplifier having a first output terminal and a second output terminal, the operational amplifier being configured to receive a gradation voltage signal representative of said video signal and to amplify said gradation voltage signal thereby to output the amplified signal via said first output terminal and said second output terminal;
a first power source line configured to supply a first power source voltage to said operational amplifier;
a second power source line configured to supply a second power source voltage to said operational amplifier;
a switching unit configured to switch between a connection of said first power source line with said high-level power source terminal and with said middle-level power source terminal and to switch between a connection of said second power source line with said middle-level power source terminal and said the low-level power source terminal;
a first transistor having a first conductivity type, with a first terminal connected to said first power source line, a second terminal connected to said signal output terminal via an output node, and a control terminal connected to said first output terminal of said operational amplifier; and
a second transistor having a second conductivity type which is opposite to said first conductivity type, with a first terminal connected to said second power source line, a second terminal connected to said signal output terminal via said output node, and a control terminal connected to said second output terminal of said operational amplifier.

2. The pixel drive voltage output circuit according to claim 1, wherein
said first transistor is a MOS transistor of a first channel type with said first terminal being a source, said second terminal being a drain, said control terminal being a gate, and a back gate being connected to said source and to said first power source line; and
said second transistor is a MOS transistor of a second channel type opposite to said first channel type, with said first terminal being a source, said second terminal being a drain, said control terminal being a gate, and a back gate connected to said source and to said second power source line.

3. The pixel drive voltage output circuit according to claim 1, wherein
said switching unit includes a first switch provided between said first power source line and said high-level power source terminal, a second switch provided between said first power source line and said middle-level power source terminal, a third switch provided between said second power source line and said middle-level power source terminal, and a fourth switch provided between said second power source line and said low-level power source terminal;
said first switch and said second switch are complementarily turned ON or OFF; and
said third switch and said fourth switch are complementarily turned ON or OFF.

4. The pixel drive voltage output circuit according to claim 1, wherein
said switching unit is configured to:
in a first period, connect said first power source line to said high-level power source terminal, and connect said second power source line to said middle-level power source terminal; and
in a second period, connect said first power source line to said middle-level power source terminal, and connect said second power source line to said low-level power source terminal.

5. A display driver configured to supply first to n-th pixel drive voltage signals to a display on a basis of a video signal that includes a train of n pieces of pixel data (n is an integer equal to two or greater), the display driver comprising:
a gradation voltage conversion unit configured to convert said n pieces of pixel data into first to n-th gradation voltage signals; and
an output unit configured to output said first to n-th pixel drive voltage signals depending on said first to n-th gradation voltage signals, wherein said output unit includes:
a high-level power source supply line configured to be supplied with a high-level power source voltage;
a low-level power source supply line configured to be supplied with a low-level power source voltage lower than said high-level power source voltage;
a middle-level power source supply line configured to be supplied with a middle-level power source voltage that is a voltage between said high-level power source voltage and said low-level power source voltage;
first to n-th signal output terminals configured to output said first to n-th pixel drive voltage signals; and
first to n-th output circuits connected to said first to n-th signal output terminals, and each of said first to n-th output circuits includes:
an operational amplifier having a first output terminal and a second output terminal, the operational amplifier being configured to output, via said first output terminal and said second output terminal, a corresponding gradation voltage signal of said first to n-th gradation voltage signals;
a first power source line configured to supply a first power source voltage to said operational amplifier;
a second power source line configured to supply a second power source voltage to said operational amplifier;
a switching unit configured to switch between a connection of said first power source line with said high-level power source supply line and with said middle-level power source supply line and to switch between a connection of said second power source line with said middle-level power source supply line and with said low-level power source supply line;
a first transistor having a first conductivity type, with a first terminal connected to said first power source line, a second terminal connected to a corresponding signal output terminal of said first to n-th signal output terminals via an output node, and a control terminal connected to said first output terminal of said operational amplifier; and
a second transistor having a second conductivity type which is opposite to said first conductivity type, with a first terminal connected to said second power source line, a second terminal connected to a corresponding signal output terminal of said first to n-th signal output terminals via the output node, and a control terminal connected to said second output terminal of said operational amplifier.

6. The display driver according to claim 5, wherein
said first to n-th output circuits include a first output circuit group and a second output circuit group that output said first to n-th pixel drive voltage signals of mutually different polarities; and
of output circuits included in said first output circuit group and output circuits included in said second output circuit group, the output circuits in one of the first output circuit group and the second output circuit group are configured such that said first power source line is connected to said high-level power source supply line, and said second power source line is connected to said middle-level power source supply line, and the output circuits in the other one of the first output circuit group and the second output circuit group are configured such that said first power source line is connected to said middle-level power source supply line, and said second power source line is connected to said low-level power source supply line.

7. The display driver according to claim 6, wherein the output circuits included in said first output circuit group are configured such that said first power source line of each output circuit is connected to said high-level power source supply line or said middle-level power source supply line via a first common line, and said second power source line of each output circuit is connected to said middle-level power source supply line or said low-level power source supply line via a second common line;
the output circuits included in said second output circuit group are configured such that said first power source line of each output circuit is connected to said high-level power source supply line or said middle-level power source supply line via a third common line, and said second power source line of each output circuit is connected to said middle-level power source supply line or said low-level power source supply line via a fourth common line; and
said switching unit switches a connection destination of said first common line and said third common line complementarily between said high-level power source supply line and said middle-level power source supply line and switches a connection destination of said second common line and said fourth common line complementarily between said middle-level power source supply line and said low-level power source supply line.
